(19) United States
(12) Patent Application Publication
(10) Pub. No.: US 2022/0389576 A1
(43) Pub. Date: Dec. 8, 2022

(54) FILM-FORMING APPARATUS AND METHOD OF USING FILM-FORMING APPARATUS

(71) Applicant: AIR WATER INC., Chuo-ku, Osaka-shi, Osaka (JP)

(72) Inventors: Hiroki URATANI, Azumino-shi, Nagano (JP); Keisuke KAWAMURA, Azumino-shi, Nagano (JP)

(21) Appl. No.: 17/779,301

(22) PCT Filed: Nov. 18, 2020
(86) PCT No.: PCT/JP2020/042945

§ 371 Date: May 24, 2022

(30) Foreign Application Priority Data
Nov. 26, 2019 (JP) 2019-212970

(51) Int. Cl. C23C 16/458; C23C 16/52; C23C 16/46; C23C 16/455; G01N 23/207

(52) U.S. Cl. CPC C23C 16/458; C23C 16/52; C23C 16/46; C23C 16/45565; G01N 23/207; G01N 2223/61

(57) ABSTRACT

A film forming apparatus and a film forming apparatus usage. The film forming apparatus has a film forming chamber, a substrate retaining part, a heating unit, a shower head, and a physical characteristics detector. The physical characteristics detector includes an irradiation part that irradiates a film formed on a surface of a substrate with a beam, a receiver to receive the beam reflected by the film, and a detection unit that detects physical characteristics of the film based on the beam received by the receiver. The shower head includes a supply plane facing the film forming plane, multiple discharge outlets provided in the supply plane, a main body to transport source gas to the multiple discharge outlets, a first transmissive part that transmits the beam emitted by the irradiation part, and a second transmissive part that transmits the reflected beam and is located at a different position than the first transmissive part.

### BACKGROUND OF THE INVENTION

### Technological Field

The present invention relates to a film forming apparatus and a film forming apparatus usage. More specifically, the present invention relates to a film forming apparatus and a film forming apparatus usage with a physical characteristics detector to detect physical characteristics of a film formed on a surface of a substrate.

### Description of the Related Art

SiC (silicon carbide) has a larger band gap than Si (silicon). SiC is thermally, chemically, and mechanically more stable than Si. For this reason, SiC is attracting attention as next-generation semiconductor devices, optical materials, and so on.

Conventionally, as a method of obtaining a single-crystal SiC, a method of making a bulk substrate consisting of SiC by a sublimation method is used. As shown in FIG. 8, as a method of obtaining a single-crystal SiC film, there is a method of which SiC film 310 is epitaxially grown on foundation substrate 300 such as a Si substrate, a SOI (Silicon On Insulator) substrate, or the like. A vacuum CVD (Chemical Vapor Deposition) method is used to make a SiC film epitaxially grown on a foundation substrate. When a vacuum CVD method is used, a SiC film is formed by using source gas, such as silane gas, hydrocarbon gas, or the like.

When the SiC film is used for power device applications, the SiC film is formed with a thickness of about 1 micrometer to 10 micrometers. Conventionally, the thickness of the SiC film was controlled by the following method based on the film forming time. The film forming time to achieve a target film thickness is calculated from the known growth rate of the SiC film. Source gas is introduced on the foundation substrate. When the calculated film forming time has elapsed, the introduction of the source gas is stopped.

In recent years, it has been considered to use SiC for purposes other than producing power devices, such producing pellicle films. When SiC is used for applications such as pellicle films, the SiC film needs to be formed with a thickness of about 10 nanometers to 100 nanometers. Moreover, control accuracy is required so that the film forming reproducibility of the SiC film thickness is 1 nanometer or less.

FIG. 9 is a diagram schematically showing an incubation time.

However, according to the conventional method with controlling the thickness of the SiC film based on film forming time, it is not able to obtain the required thickness accuracy due to the incubation time of the SiC film, with reference to FIG. 9. The incubation time is the time IT during which no film is formed from the start of the film forming to the actual start of forming of the SiC film. The incubation time is a feature found in certain conditions in film forming techniques such as the CVD. Immediately after the start of the film forming, a SiC film grows like islands, so a SiC film is not detected. It is speculated that the incubation time is due to this fact. The incubation time is disclosed in Patent Document 1 and Non-patent Document 1 below.

When a batch processing related to film forming of a SiC film is executed multiple times, even if the film forming condition for each of multiple batch processes is set to be the same, the incubation time will be different for each batch process. The cause of this is a small change in the state within the film forming chamber, such as degree of wear of jigs used for the film forming, fluctuations in the film forming start temperature due to the previous batch processing, and so on. For this reason, the conventional method with controlling the thickness of a SiC film based on film forming time has a problem that the accuracy of the thickness of the formed SiC film is low and the required thickness accuracy cannot be achieved.

Conventional film forming apparatuses are disclosed in Patent Documents 2 and 3 below. Techniques for controlling thickness of a thin film based on emissivity of light emitted from the thin film are disclosed in Patent Documents 4 and 5 below. Techniques for ellipsometry method are disclosed in Patent Documents 6-8 and Non-patent document 2 below.

### PRIOR ART DOCUMENTS

[Patent Document 1] Japanese Patent Laid-Open No. 2003-243537

[Patent. Document 2] Japanese Patent Laid-Open No. 2002-29889

[Patent Document 3] Japanese Patent No. 3597990

[Patent Document 4] Japanese Patent Laid-Open No. 2002-294461

[Patent Document 5] Japanese Patent Laid-Open No. (HEI) 5-209280

[Patent Document 6] Japanese Patent No. 3253932

[Patent Document 7] Japanese Patent Laid-Open No. 2002-194553

[Patent Document 8] Japanese Patent Laid-Open No. 2002-71462

[Non-patent Document 1] Mitsubishi Electric Corporation Shin-Gaku technical report (TECHNICAL REPORT OF IEICE) ED2000-133, SDM2000-115, ICD2000-69

[Non-patent Document 2] Saitama University Institute of Technology, Daiyu Goto, “Real-time observation of the oxidation process of non-polar hexagonal SiC surfaces”, the 74th Japan Society of Applied Physics Autumn Academic Lecture proceedings, 19a-P9-4

As a method of measuring the thickness of a SiC film, there is a method of using an emissivity measuring device. According to this method, the emissivity of the light emitted from a thin film is detected, and the thickness of the thin film is measured based on the detected emissivity. It is assumed that a conventional film forming apparatus is equipped with an emissivity measuring device.

FIG. 10 is a cross-sectional view schematically showing an example of a configuration (film forming apparatus 1100) in which an emissivity measuring device is provided to the conventional film forming apparatus.

Referring to FIG. 10, this film forming apparatus 1100 has vacuum chamber 1001, heater 1003, shower head 1004, and emissivity measuring device 1005.

The substrate 200 is held at a predetermined position within the vacuum chamber 1001 by a substrate holder (not shown). Vacuum chamber 1001 contains outlet 1011 and transparent window 1012. Outlet 1011 is an opening for exhausting the gas inside vacuum chamber 1001. A vacuum pump is connected to outlet 1011. The transparent window 1012 is provided to be located facing the film forming plane of the substrate 200 via the shower head 1004. Transparent window 1012 transmits the light emitted by emissivity measuring device 1005.

Heater 1003 heats substrate 200.

Shower head 1004 contains supply plane 1041 and through hole 1042. Supply plane 1041 faces the film forming plane (the lower surface in FIG. 10) of substrate 200. Shower head 1004 introduces source gas from outside vacuum chamber 1001. Shower head 1004 ejects the source gas to the film forming plane of substrate 200 through multiple outlets (not shown) formed in supply plane 1041 as indicated by arrow AR1001. Through hole 1042 is located between substrate 200 and transparent window 1012.

Emissivity measuring device 1005 is located outside vacuum chamber 1001 and near transparent window 1012. Emissivity measuring device 1005 emits light which has wavelength from near-infrared to near-ultraviolet. The emitted light is incident perpendicular to the film forming plane of the substrate 200 through the transparent window 1012 and through hole 1042, as indicated by the arrow AR1002. This light is reflected perpendicular to the film forming plane of substrate 200. The light reflected by the film forming plane of the substrate 200 passes through the transparent window 1012 and through hole 1042, as indicated by the arrow AR1003. Emissivity measuring device 1005 receives the reflected light that has passed through transparent window 1012 and through hole 1042. Emissivity measuring device 1005 calculates the emissivity (emissivity=1−reflected light intensity/incident light intensity) from the received reflected light, and measures the thickness of the film formed on the film forming plane of substrate 200 based on the emissivity change over time.

The inside of vacuum chamber 1001 is kept in a depressurized atmosphere. By supplying source gas from shower head 1004 to the inside of vacuum chamber 1001, the formation of a film on the film forming plane of substrate 200 is started. The film thickness is measured with emissivity measuring device 1005 during the film formation.

According to the above emissivity measuring device, the film thickness can be measured on the spot (in-situ). However, since the resolution of the film thickness detected by the above emissivity measuring device is the value calculated by “resolution=wavelength of incident light/(2* refractive index of the thin film)”, it is impossible to realize resolution of 1 nanometer or less with the incident light having wavelength from near infrared to near ultraviolet region. For this reason, according to the film forming apparatus with the emissivity measuring device mentioned above, it was difficult to form a SiC film with the thickness range of about 10 nanometers to 100 nanometers, and it was difficult to reduce the film forming reproducibility of the SiC film thickness to 1 nanometer or less.

The ellipsometry method is known as a film thickness measurement method with high resolution. According to a film thickness measuring device using the ellipsometry method, the film formed on a substrate is irradiated with light at an incident angle larger than 0 and smaller than 90-degree. The film thickness is measured based on the difference in polarized light states between the incident light and the reflected light. However, according to the conventional film forming apparatus, a gas supply unit (the shower head 1004 in FIG. 10) is provided near the film forming plane of the substrate. This gas supply unit was a barrier to the optical path, it was difficult to irradiate the film formed on the substrate with light and receive the light reflected by the film formed on substrate. As a result, it was difficult to apply a film thickness measuring device using the ellipsometry method to the conventional film forming apparatus.

The problem of low accuracy of the thickness of a film formed was not limited to the case where the film consisted of SiC, but was a problem that occurred in the whole case of forming films.

### SUMMARY OF THE INVENTION

The present invention is to solve the above problems, the purpose is to provide a film forming apparatus and a film forming apparatus usage which can improve the accuracy of the thickness of a film formed.

According to one aspect of the invention, a film forming apparatus comprising: a film forming chamber where an inside of the chamber is kept in a depressurized atmosphere, a substrate retaining part which is installed inside the film forming chamber and holds a substrate having, a film forming plane, a heating unit to heat the substrate, a gas supply unit that supplies source gas of a film to be formed on the film forming plane, to the film forming plane, and a physical characteristics detector to detect physical characteristics of the film formed on the film forming plane, wherein the physical characteristics detector includes an irradiation part that irradiates the film formed on the film forming plane with electromagnetic wave or electron beam, a receiver to receive the electromagnetic wave or the electron beam reflected by the film formed on the film forming plane, and a detection unit that detects physical characteristics of the film formed on the film forming plane, based on the electromagnetic wave or the electron beam received by the receiver, and the gas supply unit includes a supply plane facing the film forming plane, a plurality of discharge outlets provided in the supply plane and discharge the source gas toward the film forming plane, a main body that transports the source gas to the plurality of the discharge outlets, a first transmissive part that is transparent to the electromagnetic wave or the electron beam radiated from the irradiation part toward the film formed on the film forming plane, and a second transmissive part that is transparent to the electromagnetic wave or the electron beam which was reflected by the film formed on the film forming plane and heads for the receiver, wherein the second transmissive part is located at a different position from the first transmissive part.

Preferably, according to the film forming apparatus, the gas supply unit further includes a side wall that surrounds an outer circumference of the supply plane and protrudes from the supply plane toward the film forming plane, and the first and second transmissive parts are provided in the sidewall.

Preferably, according to the film forming apparatus, the first and second transmissive parts consists of notches or holes formed in the side wall.

Preferably, the film forming apparatus further comprising a size adjustment part to adjust size of each of the first and second transmissive parts.

Preferably, the film forming apparatus her comprising an angle and position adjustment unit to adjust at least one of an angle of incidence of the electromagnetic wave or the electron beam irradiated by the irradiation part to the film formed on the film forming plane, on incident position of the electromagnetic wave or the electron beam irradiated by the irradiation part on the film formed on the film forming plane, a reflection angle of the electromagnetic wave or the electron beam to be received by the receiver at the film formed on the film forming plane, and a reflection position of the electromagnetic wave or the electron beam to be received by the receiver on the film formed on the film forming plane.

Preferably, according to the film forming apparatus, the gas supply unit further includes a refrigerant flow path provided in the main body and the side wall.

Preferably, according to the film forming apparatus, the irradiation part irradiates the film formed on the film forming plane with at least one of ultraviolet light, visible light, and infrared light, the receiver receives at least one of the ultraviolet light, the visible light, and the infrared light reflected by the film formed on the film forming plane, and the detection unit detects thickness of the film formed on the film forming plane, based on change in polarized light states of at least one of the ultraviolet light, the visible light, and the infrared light received by the receiver to the polarized light states of at least one of the ultraviolet light, the visible light, and the infrared light irradiated by the irradiation part.

Preferably, according to the film forming apparatus, the substrate retaining part and the substrate divide interior of the film forming chamber into a first space and a second space, the second space is a space facing the film forming plane, and the second space is provided with the gas supply unit, and the first space has the heating unit.

Preferably, according to the film forming, apparatus, the heating unit gives radiant heat to the substrate from the opposite side of the film forming plane of the substrate.

Preferably, the film forming apparatus further comprising a control unit to control supply of the source gas by the gas supply unit, wherein the control unit stops supplying the source gas to the film forming plane, when the thickness of the film detected by the physical characteristics detector reaches a predetermined value.

Preferably, the film forming apparatus further comprising a control unit to control the heating of the substrate by the heating unit, wherein the control unit stops or changes the heating of the substrate, when the thickness of the film detected by the physical characteristics detector reaches a predetermined value.

Preferably, according to the film forming apparatus, the flow of the source gas discharged from the multiple discharge outlets and reaches the film forming plane is a molecular flow.

Preferably, the film forming apparatus further comprising a support part containing multiple pins supporting the substrate from the film forming plane side when installing the substrate on the substrate retaining part, wherein the gas supply unit further includes multiple recessed parts provided at end of the side wall on the film forming plane side, and located at different positions than the first and second transmissive parts, and each of the multiple pins penetrates each of the multiple recessed parts.

According to another aspect of the invention, a film forming apparatus usage, wherein the film forming apparatus comprising a film forming chamber where an inside of the chamber is kept in a depressurized atmosphere, a substrate retaining part which is installed inside the film forming chamber and holds a substrate with a film forming, plane, a heating unit to heal the substrate, a gas supply unit that supplies source gas of a film to be formed on the film forming plane, to the film forming plane, and a physical characteristics detector to detect physical characteristics of the film formed on the film forming plane, wherein the physical characteristics detector includes an irradiation part that irradiates the film formed on the film forming plane with electromagnetic wave or electron beam, a receiver to receive the electromagnetic wave or the electron beam reflected by the film formed on the film forming plane, and a detection unit that detects physical characteristics of the film formed on the film forming plane, based on the electromagnetic wave or the electron beam received by the receiver, and the gas supply unit includes a supply plane facing the film forming plane, a plurality of discharge outlets provided in the supply plane and discharge the source gas toward the film forming plane, and a main body that transports the source gas to the plurality of the discharge outlets, and the usage comprises: a first step to make electromagnetic wave or electron beam radiated from the irradiation part toward the film formed on the film forming plane transparent to a first transmissive part in the gas supply unit, and a second step to make the electromagnetic wave or the electron beam which was reflected by the film formed on the film forming plane and heads for the receiver transparent to a second transmissive part provided at a position different from the first transmissive part in the gas supply unit.

According to the present invention, it is possible to provide a film forming apparatus and a film forming apparatus usage which can improve the accuracy of the thickness of a formed film.

### BRIEF DESCRIPTION OF THE DRAWINGS

FIG. 1 is a cross-sectional view showing a configuration of film forming apparatus 100 in one embodiment of the present invention.

FIG. 2 is a conceptual diagram showing how to detect the thickness of the film 210 by a spectroscopic ellipsometer.

FIG. 3 is an enlarged view of part A in FIG. 1.

FIG. 4 is a plan view showing one configuration of shower head 4 when viewed from the substrate 200 side.

FIG. 5 is a cross-sectional view schematically showing the substrate 200 in which warpage occurred.

FIG. 6 is a plan view showing another configuration of shower head 4 when viewed from the substrate 200 side.

FIG. 7 is a cross-sectional view showing a configuration of a modification of film forming apparatus 100 in one embodiment of the present invention.

FIG. 8 is a cross-sectional view that schematically shows a structure of SiC film 310 epitaxially grown on foundation substrate 300 consisting of a Si substrate.

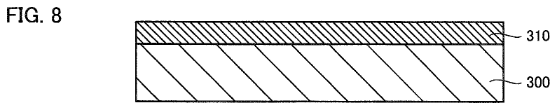

FIG. 9 is a diagram schematically showing the incubation time.

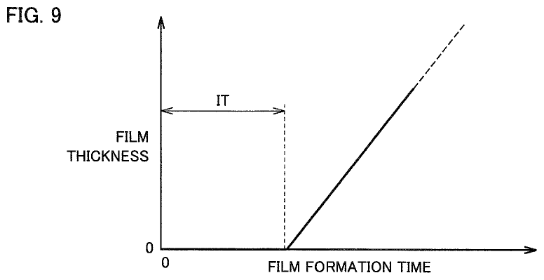

FIG. 10 is a cross-sectional view schematically showing an example of a configuration (film forming apparatus 1100) in which an emissivity measuring device is provided to the conventional film forming apparatus.

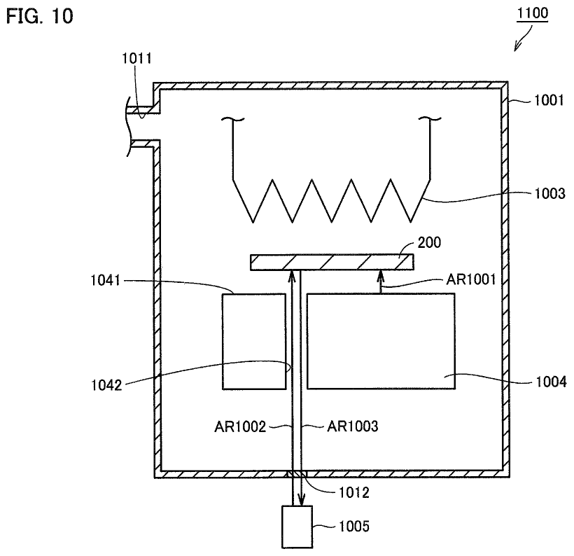

### DETAILED DESCRIPTION OF EMBODIMENTS

Hereinafter, embodiments of the present invention will be described with reference to the drawings.

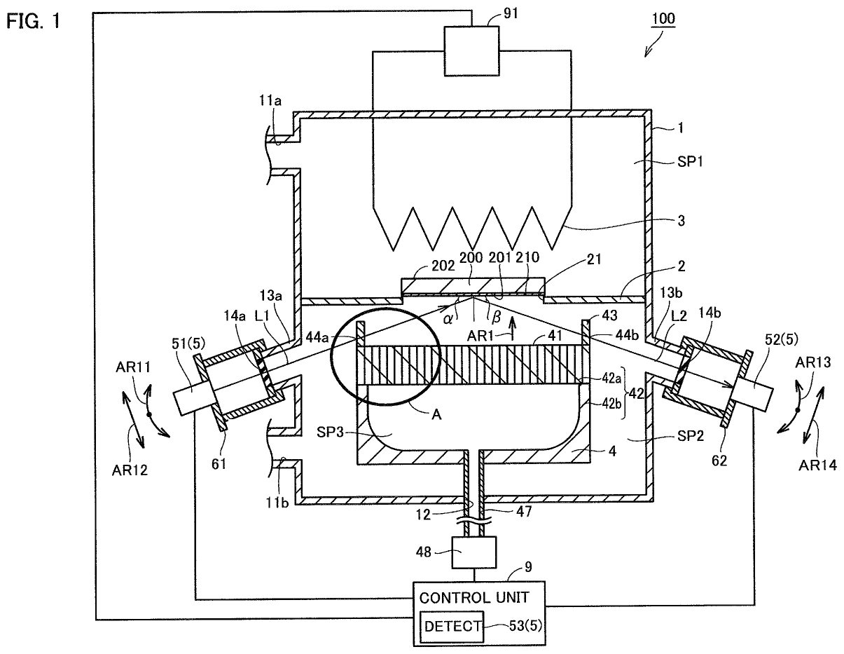

FIG. 1 is a cross-sectional view showing a configuration of film forming apparatus 100 in one embodiment of the present invention.

Referring to FIG. 1, film forming apparatus 100 (an example of a film forming apparatus) in this embodiment is for forming a film 210 on the film forming plane 201 of substrate 200 by the high vacuum CVD method. The substrate 200 is made of Si, for example. Film 210 is made of SiC, for example.

Film forming apparatus 100 has film forming chamber 1 (an example of a film forming chamber), substrate retaining part 2 (an example of a substrate retaining part), heating unit 3 (an example of a heating unit), shower head 4 (an example of a gas supply unit), physical characteristics detector 5 (an example of a physical characteristics detector), jigs 61 and 62 (an example of angle and position adjustment unit), and control unit 9.

Film forming chamber 1 contains exhaust ports 11a and 11b, port 12, protrusions 13a and 13b, and transparent windows 14a and 14b. When substrate 200 is held by substrate retaining part 2, the inside of film forming chamber 1 is divided into space SP1 and space SP2 by substrate 200 and substrate retaining part 2. Space SP1 is the space facing reverse side 202 which is the opposite side of film forming plane 201 of substrate 200. Exhaust port 11a is provided in space SP1. A vacuum pump (not shown in the figure) is connected to exhaust port 11a. Piping 47 is fixed to port 12 for gas supply to shower head 4.

Space SP2 is the space to which film forming plane 201 of substrate 200 faces. Exhaust port 11b is provided on space SP2. A vacuum pump (not shown) is connected to exhaust port 11b, which is different from the vacuum pump connected to exhaust port 11a. Each of space SP1 and SP2 is exhausted independently of each other by each of the two vacuum pumps. As a result, each of spaces SP1 and SP2 is independently controlled to be depressurized.

Port 12 is provided on space SP2. Port 12 is for introducing source gas from the outside.

Each of protrusions 13a and 13b projects diagonally downward from the outer wall of film forming chamber 1. Each of protrusions 13a and 13b faces each other. The interior of each of protrusions 13a and 13b is connected to space SP2.

Each of transparent windows 14a and 14b is attached to the tip of each of protrusions 13a and 13b. Each of transparent windows 14a and 14b consists of a material that transmits the beams L1 and L2.

Film forming chamber 1 may further include an opening (not shown) with an opening/closing mechanism. The substrate 200 is carried inside the fiim forming chamber 1 through this opening. The substrate 200 is carried from the film forming chamber 1 through this opening.

Substrate retaining part 2 is provided inside film forming chamber 1. Substrate retaining part 2 holds substrate 200. Substrate retaining part 2 protrudes from the inner wall of film forming chamber 1. The substrate 200 is placed at the edge of the aperture 21 on the top surface of the substrate retaining part 2 so as to cover the aperture 21 of the substrate retaining part 2.

Heating unit 3 is a heater that generates heat by receiving power from power supply 91. Heating unit 3 gives radiant heat to substrate 200 from the reverse side 202 of substrate 200. As a result, heating unit 3 heats substrate 200. The heating method of substrate 200 by healing unit 3 is arbitrary. Heating unit 3 may heat the substrate 200 using a resistance heating element, plasma, electromagnetic induction, or a high frequency electric field.

Shower head 4 supplies the source gas of the film to be formed on the film forming plane 201 from the source gas source 48 to the film forming plane 201.

Physical characteristics detector 5 detects the physical characteristics of the film 210 formed on the film forming plane 201. Physical characteristics detector 5 is located outside film forming chamber 1. Physical characteristics detector 5 contains irradiation part 51 (an example of an irradiation part), receiver 52 (an example of a receiver), and detection unit 53 (an example of a detection unit). Irradiation part 51 irradiates film 210 with beam L1. Irradiation part 51 is attached to protrusion 13a by jig 61. Beam L1 emitted from irradiation part 51 passes through transparent window 14a and transmissive part 44a and heads for film 210. Beam L1 passes through transmissive part 44a and then enters film 210.

Receiver 52 receives beam L2, which is beam L1 reflected by film 210. Receiver 52 is attached to protrusion 13b by jig 62. Reflected light 12 reflected by film 210 passes through transmissive part 44b and transparent window 14b and heads for receiver 52. Beam L2 passes through transparent window 14b and then enters receiver 52. Beam L1 and beam L2 consist of electromagnetic waves or electron beams.

The angle formed by the optical axis of the beam L1 and film forming plane 201 (the substrate horizontal plane) is defined as the incident angle α. The angle formed by the optical axis of the beam L2 and film forming plane 201 is defined as the reflection angle β. Each of the incident angle α and the reflection angle β is larger than 0. Each of the incident angle α and the reflection angle β is preferably 15 degrees or more and 30 degrees or less.

Physical characteristics detector 5 may be provided inside film forming chamber 1.

The jig 61 can rotate the irradiation part 51 attached to the protrusion 13a, as indicated by the arrow AR11. By this rotation, jig 61 adjusts the incident angle α. The jig 61 can move the irradiation part 51 attached to the protrusion 13a in the vertical and horizontal directions as shown by the arrow AR12. By this movement, the jig 61 adjusts the position of the beam L1 on the film 210.

Similarly, the jig 62 can rotate the receiver 52 attached to the protrusion 13b, as indicated by the arrow AR13. By this rotation, jig 62 adjusts the angle of receiver 52 with respect to the reflection angle β. The jig 62 can move the receiver 52 attached to the protrusion 13b the vertical and horizontal directions as shown by the arrow AR14. By this movement, jig 62 adjusts the position or receiver 52 with respect to beam L2.

Detection unit 53 detects physical characteristics of film 210 based on the beam L2 received by receiver 52. In this embodiment, the case where control unit 9 has the function of detection unit 53 is shown. Detection unit 53 may operate independently or control unit 9.

Control unit 9 controls the supply of source gas by shower head 4, by controlling the opening and closing of the valve of source gas source 48. Control unit 9 controls the heating temperature of substrate 200 by controlling the input power to heating, unit 3. Control unit 9 stops supplying source gas to film forming plane 201 when the thickness of film 210 detected by physical characteristics detector 5 reaches a predetermined value. Control unit 9 controls to stop heating substrate 200 or change the heating temperature when the thickness of film 210 detected by physical characteristics detector 5 reaches a predetermined value. Also, control unit 9 controls the operation of power supply 91, irradiation part 51, and receiver 52 respectively.

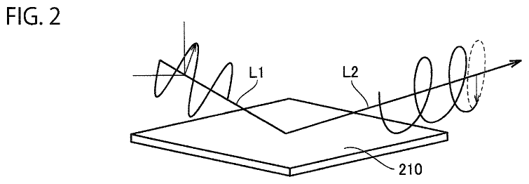

FIG. 2 is a conceptual diagram showing how to detect the thickness of the film 210 by a spectroscopic ellipsometer.

Referring to FIGS. 1 and 2, physical characteristics detector 5 may consist of a spectroscopic ellipsometer. If physical characteristics detector 5 consists of a spectroscopic ellipsometer, irradiation part 51 irradiates light as beam L1. Receiver 52 receives the light as beam L2. The beams L1 and L2 are preferably at least one of ultraviolet light, visible light, and infrared light.

Detection unit 53 detects the thickness of film 210 based on the change in the polarized light state of the light received by receiver 52 with respect to the polarized light state of the light emitted by irradiation part 51.

Physical characteristics detector 5 may be an RHEED (Reflection High Energy Electron Diffraction) device, an X-ray reflectance measuring device, or the like.

If physical characteristics detector 5 consists of a RHEED device, irradiation part 51 irradiates an electron beam as beam L1. Receiver 52 the electron beam as beam L2. Detection unit 53 detects the thickness of film 210 and the state of the grid of the surface of film 210 based on the diffraction pattern of the electron beam received by receiver 52.

If physical characteristics detector 5 consists of an X-ray reflectance measuring device, then irradiation part 51 irradiates X-ray as beam L1. Receiver 52 receives the X-ray as beam L2. Based on the dependence of reflectance of X-ray received at receiver 52 with respect to the incident angle, detection unit 53 detects the thickness of film 210, the density of film 210, or the surface roughness of film 210.

Next, the details of shower head 4 will be explained.

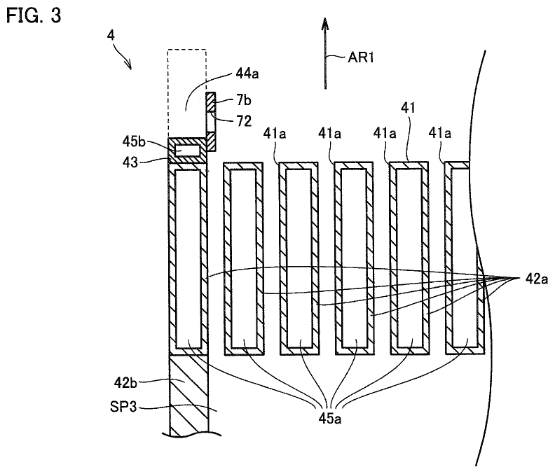

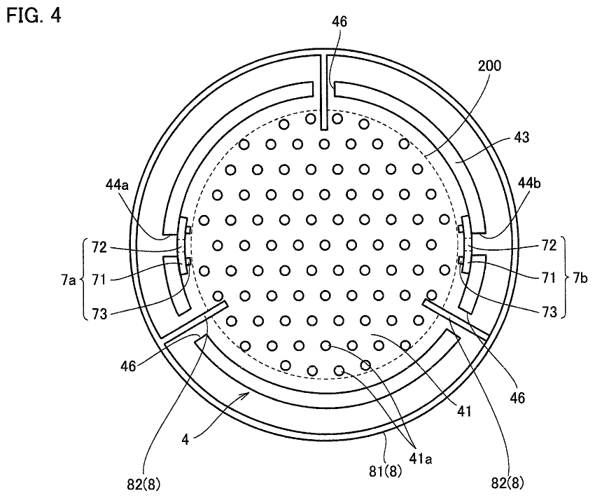

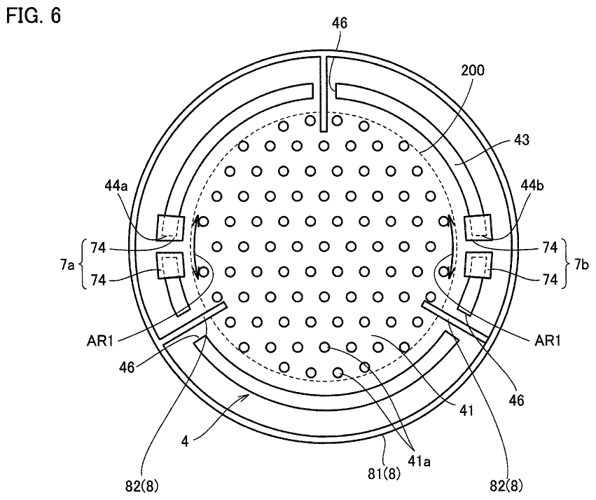

FIG. 3 is an enlarged view of part A in FIG. 1. FIG. 4 is a plan view showing one configuration of shower head 4 when viewed from the substrate 200 side. In FIGS. 4 and 6, the location of substrate 200 is shown by the dotted line.

With reference to FIGS. 1, 3, and 4, shower head 4 contains supply plane 41 (an example of a supply plane), discharge outlets 41a (an example of discharge outlets), main body 42 (an example of a main body), side wall 43, transmissive parts 44a and 44b (an example of first and second transmissive parts), flow paths 45a and 45b, and recessed part 46.

Supply plane 41 is located at the top of shower head 4. Supply plane 41 faces film forming plane 201. Supply plane 41 is a plane and is almost parallel to film forming plane 201. Here, substrate 200 and supply plane 41 have a circle planar shape. Planar shapes of substrate 200 and supply plane 41 are optional.

Each of the multiple discharge outlets 41a is located in supply plane 41. Each of the multiple discharge outlets 41a discharges source gas evenly towards film forming plane 201. By ejecting source gas from each of the multiple discharge outlets 41a of supply plane 41 facing film forming plane 201 of substrate 200, the thickness of film 210 formed on film forming plane 201 can be made uniform.

Main body 42 transports source gas carried from piping 47 to multiple discharge outlets 41a. Main body 42 includes upper main body 42a and lower main body 42b. Upper main body 42a is located on top of lower main body 42b. Multiple discharge outlets 41a are formed in upper main body 42a. Lower main body 42b contains internal space SP3. Each of the multiple discharge outlets 41a extends from the bottom surface of upper main body 42a facing internal space SP3 to supply plane 41.

Side wall 43 surrounds the circumference of supply plane 41. Side wall 43 protrudes upward from supply plane 41 toward film forming plane 201. When viewed from the substrate 200 side, the side wall 43 has a circular planar shape. Side wall 43 serves to fill the inside of side wall 43 with source gas discharged from multiple discharge outlets 41a. When viewed from the normal direction of supply plane 41, side wall 43 surrounds the circumference of substrate 200. As a result, source gas ejected from multiple discharge outlets 41a can be distributed throughout film forming plane 201. Side wall 43 consists of a material that shields beam L1 and beam L2. Side wall 43 may consist of a material that transmits beam L1 and beam L2. In this case, each of side wall 43 and transmissive parts 44a and 44b may be made of the same member.

Each of transmissive parts 44a and 44b is provided on side wall 43. Each of transmissive parts 44a and 44b is made by a notch or hole formed in, for example, side wall 43. As a result, beam L1 passes through transmissive part 44a. Beam L2 passes through transmissive, part 44b. Each of transmissive parts 44a and 44b is provided at a position through which each of beam L1 and beam L2 passes. Each of transmissive parts 44a and 44b is located in a different position from each other. Each of transmissive parts 44a and 44b has a similar configuration.

Each of flow paths 45a and 45b is the refrigerant flow path for cooling shower head 4. Flow path 45a is located inside upper main body 42a. Plow path 45b is located inside side wall 43. Each of flow paths 45a and 45b is connected with an introduction pipe (not shown) for introducing the refrigerant into the flow path and an a discharge pipe (not shown) for discharging the refrigerant from the flow path.

When forming a film, as substrate 200 is heated, the internal structure of film forming chamber is heated. When source gas is supplied inside film forming chamber 1 in this state, not only is film 210 formed on film forming plane 201 of substrate 200, but source gas also reacts near the internal structure of film forming chamber 1. As a result, deposits (foreign matters) are formed on the internal structure of film forming chamber 1. If such deposits are unnecessarily exfoliated and scattered, the deposits adhere to substrate 200. As a result, substrate 200 is contaminated. By circulating the refrigerant through flow paths 45a and 45b when forming a film, the temperature of the internal structures of film forming chamber 1 (especially upper main body 42a and side wall 43) can be cooled below the reaction temperature of source gas. As a result, it is possible to suppress the adhesion of deposits to shower head 4.

Multiple recessed parts 46 are provided at the end of side wall 43 on the film forming plane 201 side. Multiple recessed parts 46 are located differently from transmissive parts 44a and 44b of side wall 43.

Piping 47 carries gas to main body 42. Piping 47 is connected to main body 42 and source gas source 48.

Source gas source 48 is a container for storing source gas. Source gas source 48 is located outside film forming chamber 1.

The film forming apparatus 100 has also size adjustment parts 7a and 7b, and support part 8.

Size adjustment parts 7a and 7b are mounted in opposite positions on side wall 43. Each of size adjustment part 7a and 7b has a similar configuration. Each or size adjustment parts 7a and 7b contains shielding plate 71, transmissive part 72, and screw 73. Each of size adjustment parts 7a and 7b is removable to side wall 43 by screw 73.

When viewed from the substrate 200 side, the shielding plate 71 has an arc planar shape along the side wall 43. Shielding plate 71 is fixed by screw 73 in a position covering each of transmissive parts 44a and 44b in side wall 43. Shielding plate 71 consists of a material that shields beam L1 and beam L2.

Transmissive part 72 is located in shielding plate 71. Transmissive part 72 consists of a notch or a hole formed in, for example, shielding plate 71. As a result, beam L1 and beam L2 passes through transmissive part 72.

The film forming apparatus 100 has multiple types of size adjustment parts 7a and 7b, including multiple sizes of transmissive part 72. The film forming apparatus 100 users select each of size adjustment parts 7a and 7b, including appropriately sized transmissive part 72, depending on the type of substrate 200 and the type of the film to be formed on the substrate, etc. The film forming apparatus 100 users attach each of the selected size adjustment parts 7a and 7b to side wall 43 before forming the film. As a result, the respective sizes of transmissive parts 44a and 44b (the size of the area through which the beam L1 or L2 passes) are adjusted by each of size adjustment parts 7a and 7b.

In order to prevent the leakage of source gas to the outside of side wall 43, it is preferable that each of transmissive parts 44a and 44b is adjusted to the smallest possible size within the range where beam L1 and beam L2 can pass through.

Support part 8 contains support part main body 81 and multiple pins 82. The support part main body 81 has a circumferential planar shape when viewed front the substrate 200 side. Multiple pins 82 support the substrate 200 from the film forming plane 201 side, when installing the substrate 200 on the substrate retaining part 2. Each of the multiple pins 82 projects inward from support part main body 81. Each of the plurality of pins 82 is provided at equal intervals with respect to support part main body 81.

Each of the multiple pins 82 is inserted into each of the multiple recessed parts 46, except when the substrate 200 is being installed on the substrate retaining part 2. Each of the plurality of pins 82 penetrates each of the plurality of recessed parts 46 and projects onto the supply plane 41. When installing substrate 200 on substrate retaining part 2, each of the plurality of pins 82 moves from substrate retaining part 2 toward supply plane 41 with substrate 200 being supported from the film forming plane 201 side. As a result, substrate 200 is transported to substrate retaining part 2.

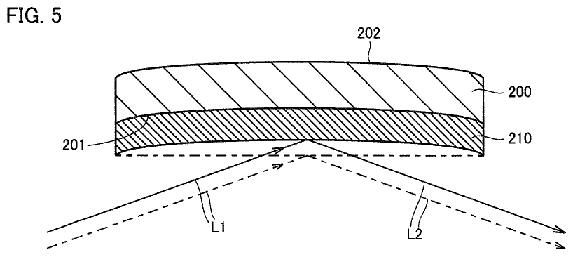

FIG. 5 is a cross-sectional view schematically showing the substrate 200 in which warpage occurred.

Referring to FIGS. 1 and 5, the jig 61 can rotate the irradiation part 51 attached to the protrusion 13a, as indicated by the arrow AR11. By this rotation, jig 61 adjusts the incident angle α. The jig 61 can move the irradiation part 51 attached to the protrusion 13a in the vertical and horizontal directions as shown by the arrow AR12. By this movement, jig 61 adjusts the position of incidence on film 210.

Similarly, the jig 62 can rotate the receiver 52 attached to the protrusion 13b, as indicated by the arrow AR13. By this rotation, jig 62 adjusts the angle of receiver 52 with respect to the reflection angle β. The jig 62 can move the receiver 52 attached to the protrusion 13b in the vertical and horizontal directions as shown by the arrow AR14. This movement causes jig 62 to adjust the position of receiver 52 with respect to beam L2.

When making film 210 hetero epitaxial growth on film forming plane 201 of substrate 200, and the film is made of a material different from that of substrate 200 (typically, when substrate 200 consists of Si and film 210 consists of SiC), due to the difference in thermal expansion coefficients between substrate 200 and film 210, substrate 200 will have warpage as shown in FIG. 5. When warpage occurs in substrate 200, the reflection position of beam L1 on film 210 changes, and the path or beam L2 may change from the original path. As a result, the amount of beam L2 received by receiver 52 may be significantly reduced.

Therefore, by providing jig 61 or 62, even if the path of the beam L2 changes from the original path due to warpage of substrate 200 etc., the beam L2 can be stably received by receiver 52.

FIG. 6 is a plan view showing another configuration of shower head 4 when viewed from the substrate 200 side.

Referring to FIG. 6, each of size adjustment parts 7a and 7b may have the following configuration. Each of size, adjustment parts 7a and 7b contains two shielding plates 74. Each of the two shielding plates 74 is mounted near transmissive part 44a or 44b of side wall 43. Each of the two shielding plates 74 can move along the side wall 43, as indicated by the arrow AR1. Each of the two shielding plates 74 consists of a material that shields beam L1 and beam L2.

Film forming apparatus 100 users adjusts the spacing between the two shielding plates 74, depending on the type of substrate 200 and the type of the film to be formed on the substrate, etc. As a result, the respective sizes of transmissive parts 44a and 44b (the circumferential length of the region through which beam L1 or L2 passes) are adjusted by each of size adjustment part 7a and 7b.

The flow of source gas discharged horn multiple discharge outlets 41a and reaches film forming plane 210 is a molecular flow. The pressure of space SP2 is set so that this source gas flow becomes a molecular flow.

That is, it is defined that pressure in space SP2 is P (Pa), temperature in space SP2 is temperature T (K), diameter of the molecule that makes up source gas is diameter d (m), and Boltzmann constant value is constant value k (J/K), the mean free path λ of the molecules that make up source gas is expressed by the following equation (1).

λ=kT/(√2*π*d\hat{ }2*P) (1)

Let the distance D be the distance from each of the plurality of discharge outlets 41a to film forming dare 201 of substrate 200. The Knudsen number K is expressed by the following equation (2).

K=λ/D (2)

In order to make the flow of source gas discharged from multiple discharge outlets 41a and reaches film forming plane 210 to a molecular flow, the Knudsen number K of the molecules constituting source gas must satisfy the following equation (3).

K>0.3 (3)

As an example of conditions under which the flow of source gas becomes a molecular flow, when a SiC film is formed, the pressure P at the film forming is 0<P<1 * 10\hat{ }−1 (Pa), and die distance D is 1 (cm) <D<100 (cm).

[Effect of the Embodiment]

According to she above embodiment, transmissive parts 44a and 44b provided in shower head 4 secure the path of beam L1 and beam L2. As a result, physical characteristics of film 210 formed on film forming plane 201 can be detected by physical characteristics detector 5. The accuracy of the thickness of the formed film 210 can be improved.

According to the above embodiment, if substrate 200 is made of Si and film 210 is a film made of SiC with a thickness of about 10 nanometers to 100 nanometers, the thickness distribution over the entire film 210 can be less than or equal to 1 nanometer.

[Modification]

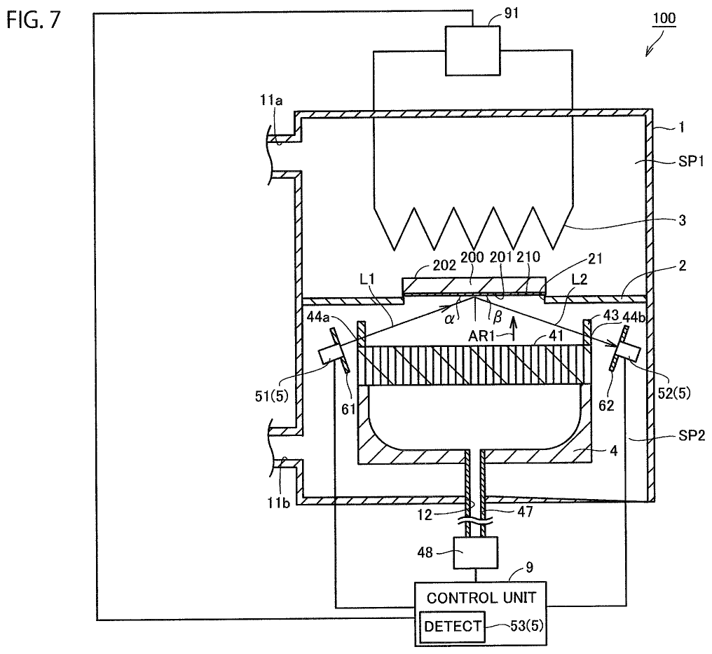

If the beams L1 and L2 consist of electron beam, extreme ultraviolet, or X-ray etc., there are few suitable materials for transparent windows 14a and 14b. Suitable materials for transparent windows 14a and 14b are materials with high transmittance for beam L1 or L2 while maintaining the depressurized atmosphere inside film forming chamber 1. Therefore, like modification shown In FIG. 7, physical characteristics detector 5 may be provided inside film forming chamber 1 for the purpose of reducing the loss of beams L1 and L2 when beams L1 and L2 pass through film forming chamber 1.

FIG. 7 is a cross-sectional view showing the configuration of a modification of film forming apparatus 100 in one embodiment of the present invention.

Referring to FIG. 7, according to film forming apparatus 100 of this modification, physical characteristics detector 5 and jigs 61 and 62 are provided inside film forming chamber 1.

The beam L1 emitted from irradiation part 51 passes through transmissive part 44a and enters fiim 210. The beam L2 reflected by film 210 passes through transmissive part 44b and is incident on receiver 52. Film forming chamber 1 does not include protrusions 13a and 13b, as well as transparent windows 14a and 14b.

[Others]

The placement and orientation of each member of film forming apparatus 100 in each of FIGS. 1 and 7 may be upside down. In particular, shower head 4 may be provided in space SP1 and heater 3 may be provided in space SP2. Substrate retaining part may hold the reverse, side 202 of the substrate 200 and the film forming plane 201 of the substrate 200 may face upwards. The shower head 4 may supply gas downwards toward film forming plane 201 of substrate 200. However, support part 8 is provided on the reverse side 202 of substrate 200. As in FIGS. 1 and 7, support part 8 lifts the substrate 200 from below the substrate 200.

Each of transmissive parts 44a, 44b, and 72 may be an optical through hole, and it may be made of transmissive part materials that is transparent to electromagnetic wave or electron beam, instead of being made of notches or holes. However, considering the decrease in transmittance due to foreign matters adhering to the transmissive part when forming a film, each of transmissive parts 44a, 44b, and 72 is preferably composed of it notch or a hole.

The location where transmissive parts 44a and 44b are installed does not have to be side wall 43. Transmissive parts 44a and 44b may be provided at any position of shower head 4.

The film forming apparatus may be a CVD device or a vapor deposition device such as an MBE (Molecular Beam Epitaxy) device. If the film forming apparatus is a vapor deposition device, the first and second transmissive parts may be provided at a vapor deposition source such as Knudsen-Cells.

The above embodiments and modifications can be combined as appropriate.

The embodiments and modifications described above should be considered in all respects as exemplary and not restrictive. The scope of the present invention is shown not by the above description but by the scope of the claims, and is intended to include meanings equivalent to the scope of the claims and all modifications within the scope.

### EXPLANATION OF SYMBOLS

1 film forming chamber (an example of a film forming chamber)

2 substrate retaining part (an example of a substrate retaining part)

3 heating unit (an example of a heating unit)

4, 1004 shower head (an example of a gas supply unit)

5 physical characteristics detector (an example of a physical characteristics detector)

7a, 7b size adjustment part

8 support part

9 control unit

11a, 11b, 1011 exhaust port

12 port

13a, 13b protrusion

14a, 14b, 1012 transparent window

21 aperture

41, 1041 supply plane (an example of a supply plane)

41a discharge outlets (an example of discharge outlets)

42 main body (an example of a main body)

42a upper main body

42b lower main body

43 side wall

44a, 44b, 72 transmissive part (an example of first and second transmissive parts)

45a, 45b flow path

46 recessed part

47 piping for gas supply

48 source gas source

51 irradiation part (an example of an irradiation part)

52 receiver (an example of a receiver)

53 detection unit (an example of a detection unit)

61, 62 jig (an example of an angle and position adjustment unit)

71, 74 shielding plate

73 screw

81 support part main body

82 pin

91 power supply

100, 1100 film forming apparatus (an example of a film forming apparatus)

200 substrate

201 film forming plane

202 reverse side

210 film

300 foundation substrate

310 SiC film

1001 vacuum chamber

1003 heater

1005 emissivity measuring device

1042 through hole

L1, L2 electromagnetic wave or electron beam

SP1, SP2 space

SP3 internal space

What is claimed is:

1. A film forming apparatus comprising:
a film forming chamber where an inside of the chamber is kept in a depressurized atmosphere,
a substrate retaining part which is installed inside the film forming chamber and holds a substrate having a film forming plane,
a heating unit to heat the substrate,
a gas supply unit that supplies source gas of a film to be formed on the film forming plane, to the film forming plane, and
a physical characteristics detector to detect physical characteristics of the film formed on the film forming plane, wherein
the physical characteristics detector includes
an irradiation part that irradiates the film formed on the film forming plane with electromagnetic wave or electron beam,
a receiver to receive the electromagnetic wave or the electron beam reflected by the film formed on the film forming plane, and
a detection unit that detects physical characteristics of the film formed on the film forming plane, based on the electromagnetic wave or the electron beam received by the receiver, and
the gas supply unit includes
a supply plane facing the film forming plane,
a plurality of discharge outlets provided in the supply plane and discharge the source gas toward the film forming plane,
a main body that transports the source gas to the plurality of the discharge outlets,
a first transmissive part that is transparent to the electromagnetic wave or the electron beam radiated from the irradiation part toward the film formed on the film forming plane, and
a second transmissive part that is transparent to the electromagnetic wave or the electron beam which was reflected by the film formed on the film forming plane and heads for the receiver, wherein the second transmissive part is located at a different position from the first transmissive part.

2. The film forming apparatus according to claim 1, wherein
the gas supply unit further includes a side wall that surrounds an outer circumference or the supply plane and protrudes from the supply plane toward the film fruiting plane, and
the first and second transmissive parts are provided in the sidewall.

3. The film forming apparatus according to claim 2, wherein
the first and second transmissive parts consists of notches or holes formed in the side wall.

4. The film forming apparatus according to claim 3, further comprising
a size adjustment part to adjust size of each of the first and second transmissive parts.

5. The film forming apparatus according to claim 1, further comprising
an angle and position adjustment unit to adjust at least one of an angle of incidence of the electromagnetic wave or the electron beam irradiated by the irradiation part to the film formed on the film forming plane, an incident position of the electromagnetic wave or the electron beam irradiated by the irradiation part on the film formed on the film forming plane, a reflection angle of the electromagnetic wave or the electron beam to be received by the receiver at the film formed on the film forming plane, and a reflection position of the electromagnetic wave or the electron beam to be received by the receiver on the film formed on the film forming plane.

6. The film forming apparatus according to claim 2, wherein
the gas supply unit further includes a refrigerant flow path provided in the main body and the side wall.

7. The film forming apparatus according to claim 1, wherein
the irradiation part irradiates the film formed on the film forming plane with at least one of ultraviolet light, visible light, and infrared light,
the receiver receives at least one of the ultraviolet light, the visible light, and the infrared light reflected by the film formed on the film forming plane, and
the detection unit detects thickness of the film formed on the film forming plane, based on change in polarized light states of at least one of the ultraviolet light, the visible light, and the infrared light received by the receiver to the polarized light states of at least one of the ultraviolet light, the visible light, and the infrared light irradiated by the irradiation part.

8. The film fanning apparatus according to claim 1, wherein
the substrate retaining part and the substrate divide interior of the film forming chamber into a first space and a second space,
the second space is a space facing the film forming plane, and the second space is provided with the gas supply unit, and
the first space has the heating unit.

9. The film forming apparatus according to claim 1, wherein
the heating unit gives radiant heat to the substrate from the opposite side of the film forming plane of the substrate.

10. The film forming apparatus according to claim 1, further comprising
a control unit to control supply of the source gas by the gas supply unit, wherein
the control unit stops supplying the source gas to the film forming plane, when the thickness of the film detected by the physical characteristics detector reaches a predetermined value.

11. The film forming apparatus according to claim 1, further comprising
a control unit to control the heating of the substrate by the heating unit, wherein
the control unit stops or changes the heating of the substrate, when the thickness of the film detected by the physical characteristics detector reaches a predetermined value.

12. The film forming apparatus according to claim 1, wherein
the flow of the source gas discharged from the multiple discharge outlets and reaches the film forming plane is a molecular flow.

13. The film forming apparatus according to claim 2, further comprising
a support part containing multiple pins supporting the substrate from the film forming plane side when installing the substrate on the substrate retaining part, wherein
the gas supply unit further includes multiple recessed parts provided at end of the side wall on the film forming plane side, and located at different positions than the first and second transmissive parts, and
each of the multiple pins penetrates each of the multiple recessed parts.

14. A film limning apparatus usage, wherein
the film forming apparatus comprising
a film forming chamber where an inside of the chamber is kept in a depressurized atmosphere,
a substrate retaining part which is installed inside the film forming chamber and holds a substrate with a film forming plane,
a heating unit to heat the substrate,
a gas supply unit that supplies source gas of a film to be formed on the film forming plane, to the film forming plane, and
a physical characteristics detector to detect physical characteristics of the film formed on the film forming plane, wherein
the physical characteristics detector includes
an irradiation part that irradiates the film formed on the film forming plane with electromagnetic wave or electron beam,
a receiver to receive the electromagnetic wave or the electron beam reflected by the film formed on the film forming plane, and
a detection unit that detects physical characteristics of the film formed on the film forming plane, based on the electromagnetic wave or the electron beam received by the receiver, and
the gas supply unit includes
a supply plane facing the film forming plane,
a plurality of discharge outlets provided in the supply plane and discharge the source gas toward the film forming plane, and
a main body that transports the source gas to the plurality of the discharge outlets, and
the usage comprises:
a first step to make electromagnetic wave or electron beam radiated from the irradiation part toward the film formed on the forming plane transparent to a first transmissive part in the gas supply unit, and
a second step to make the electromagnetic wave or the electron beam which was reflected by the film formed on the film forming plane and heads for the receiver transparent to a second transmissive part provided at a position different from the first transmissive part in the gas supply unit.
